(19) United States
(12) Patent Application Publication
(10) Pub. No.: US 2025/0306066 A1
(43) Pub. Date: Oct. 2, 2025

(54) POWER EFFICIENCY CALCULATION DEVICE, POWER EFFICIENCY CALCULATION METHOD, POWER EFFICIENCY CALCULATION SYSTEM, AND PROGRAM

(71) Applicant: Nippon Telegraph and Telephone Corporation, Tokyo (JP)

(72) Inventor: Yoshito ITO, Musashino-shi, Tokyo (JP)

(21) Appl. No.: 18/864,776

(22) PCT Filed: May 26, 2022
(86) PCT No.: PCT/JP2022/021617

§ 371 Date: Nov. 11, 2024

(51) Int. Cl. G01R 21/133

(52) U.S. Cl. CPC G01R 21/133

(57) ABSTRACT

A power efficiency calculation device includes a metrics collection unit that collects metrics from a physical server group, a task execution amount normalization unit that determines a normalization coefficient for each task of each application, an importance group setting unit that sets importance groups of each application and each task to determine weights, and a power efficiency calculation unit that normalizes a task execution amount using the normalization coefficient, calculates a total work output by using the normalized task execution amount and the weight of the importance group of the application and the task, and calculates power efficiency.

### TECHNICAL FIELD

The present invention relates to a power efficiency calculation device, a power efficiency calculation method, a power efficiency calculation system, and a program, for calculating power efficiency for application processing.

### BACKGROUND ART

Various definitions have been proposed for a power efficiency index of a data center. Among them, the only index which can be measured and calculated in real time as to with what degree of power efficiency a specific application can be operated is Data Center energy Productivity (DCeP) (refer to NPL 1). DCeP is defined in Equation (1) below.

$$\begin{matrix}[ Math . 1 ] & \\ DCeP = \frac{Useful Work Produced}{Total Energy Consumed to Perform that Work} & Equation ( 1 )\end{matrix}$$

DCeP (power efficiency) is defined as a “useful work produced” (referred to herein as “work output”) divided by “total energy consumed to perform that work” (referred to herein as “power consumption”).

Further, the “useful work produced” (work output) is defined by Equation (2) below.

$$\begin{matrix}[ Math . 2 ] & \\ Usefule Work Produced = {\sum }_{i = 1}^{M} {V}_{i} * {U}_{i} ( t , T ) * {T}_{i} & Equation ( 2 )\end{matrix}$$

Here, “M” denotes the number of tasks started in an assessment window, “Vᵢ” denotes a normalization coefficient obtained by summing up numerical values of the tasks, “Uᵢ (t, T)” denotes a time-based utility function of each task, “t” denotes an elapsed time from start to completion of the task, and “T” denotes an absolute time at task completion.

NPL 1 proposes setting a weight coefficient for a task for “useful work produced” (work output) and adjusting balance of values between tasks. However, NPL 1 fails to mention of a specific method for adjusting the balance. Further, NPL 1 describes only “an interval of 20 times or more of task execution is desirable” for the assessment window which is a measurement interval.

Further, NPL 2 describes results of calculating DCeP with “useful work produced” (work output) defined as energy consumed when various applications are processed in a high performance computing (HPC) data center. However, in NPL 2, all tasks are handled equivalently without considering a weight for each application type or importance of processing between tasks.

Further, in NPL 3, “useful work produced” (work output) is defined as the number of times two kinds of applications are executed (useful computational units) within a certain time, and the number of executions when each application has been executed with a weight coefficient (1:0.08) is normalized.

### CITATION LIST

### Non Patent Literature

[NPL 1] D. Anderson, et al., “A framework for data center energy productivity”, The Green Grid, 2008.
[NPL 2] A. Grishina, et al., “DC energy data measurement and analysis for productivity and waste energy assessment”, 2018 IEEE International Conference on Computational Science and Engineering (CSE), IEEE, 2018.
[NPL 3] Landon H. Sego, et al., “Implementing the data center energy productivity metric”, ACM Journal on Emerging Technologies in Computing Systems (JETC) 8.4 (2012): 1-22.

### SUMMARY OF INVENTION

### Technical Problem

The calculation of DCeP described in NPL 1 to NPL 3 above does not consider a weight for each application type or an importance of processing between tasks. Therefore, even when there is a difference in importance of processing and service level agreement (SLA) between applications or between tasks in a single application, a processing amount (“useful work produced”) considering weights between the applications and between the tasks cannot be calculated, and a power efficiency value cannot be calculated appropriately. This means that NPL 1 to NPL 3 does not define a weight setting scheme based on each application type or importance of processing between tasks in the calculation of DCeP.

For example, as illustrated in FIG. 7, the number of times the application is executed is determined as a processing amount of tasks, and power efficiency is calculated as a sum of two kinds of tasks (task A and task B). In this case, when it is assumed that the numbers of times the tasks are executed are respectively 1,000 times and one time per unit time, and that the weight is not set, the power efficiency substantially reflects only a result of the task A. Therefore, even when task B is important processing, this is not considered.

In view of such a problem, the present invention has been made, and an object of the present invention is to calculate power efficiency reflecting importance of applications or tasks.

### Solution to Problem

A power efficiency calculation device according to the present invention is a power efficiency calculation device for calculating power efficiency by executing an application installed on a physical server group, wherein one or more applications for executing one or more tasks are installed in the physical server group, and the power efficiency calculation device comprises: a metrics collection unit configured to collect metrics from the physical server group, the metrics being an assessment index necessary for power efficiency calculation and including a task execution amount and power consumption of the physical server group, and to store the metrics in a metrics collection DB in a storage unit; a task execution amount normalization unit configured to acquire the task execution amount stored in the metrics collection DB and determine a normalization coefficient for each task of each application by using the task execution amount measured for each predetermined measurement time;
an importance group setting unit configured to perform setting of an importance group regarding each application and each task on the basis of a predetermined importance group setting logic, and to set a weight according to importance of each of an importance group of each application and an importance group of each task; and a power efficiency calculation unit configured to acquire metrics of a predetermined assessment period collected by the metrics collection unit, normalize the task execution amount included in the metrics by using the normalization coefficient for each task of each application, calculate a total work output using the normalized task execution amount and a weight of each importance group of each application and each task, and calculate power efficiency from the power consumption included in the metrics and the total work output.

### Advantageous Effects of Invention

According to the present invention, it is possible to calculate power efficiency reflecting importance of applications and tasks.

### BRIEF DESCRIPTION OF DRAWINGS

FIG. 1 is a diagram illustrating a calculation equation for “useful work produced” (work output) according to the present embodiment.

FIG. 2 is a diagram for describing a calculation equation for “useful work produced” (work output) according to the present embodiment.

FIG. 3 is a diagram illustrating an overall configuration of a power efficiency calculation system including a power efficiency calculation device according to the present embodiment.

FIG. 4 is a diagram illustrating a maximum number of times a request is processed within a predetermined period, the maximum number being collected by the power efficiency calculation device according to the present embodiment.

FIG. 5 is a flowchart illustrating a flow of processing executed by the power efficiency calculation device according to the present embodiment.

FIG. 6 is a hardware configuration diagram illustrating an example of a computer that implements functions of the power efficiency calculation device according to the present embodiment.

FIG. 7 is a diagram illustrating a problem in calculation of power efficiency in the conventional art without considering a weight between applications or between tasks.

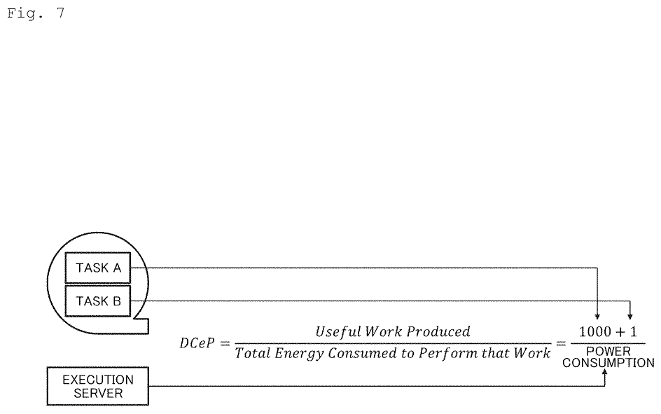

### DESCRIPTION OF EMBODIMENTS

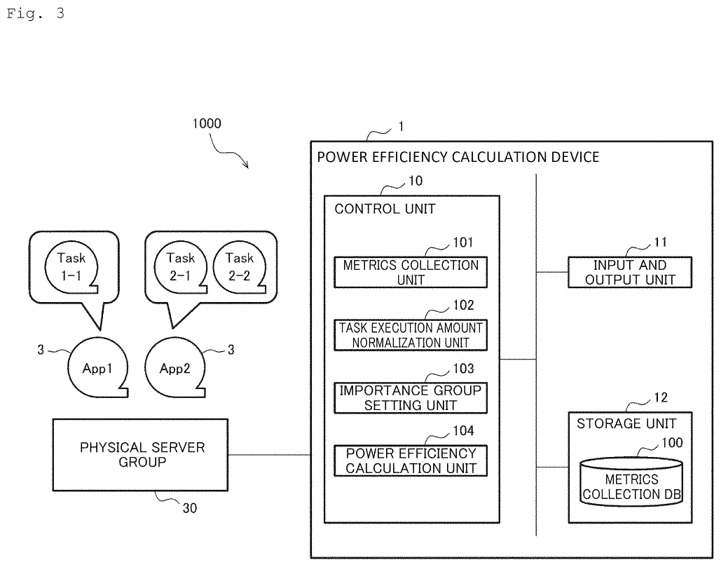

Next, an embodiment for carrying out the present invention (hereinafter referred to as “the present embodiment”) is described. First, an overview of a power efficiency calculation device 1 (see FIG. 3 described below) according to an embodiment of the present invention is described.

### <Overview>

The power efficiency calculation device 1 according to the present embodiment is a device for calculating power efficiency in consideration of importance of one or more applications (Apps) and one or more tasks executed by the applications.

As an index of the power efficiency, DCeP (power efficiency) shown in Equation (1) above is used. Further, in the present embodiment, weight coefficients are defined for the application and the task in a calculation of “useful work produced” (work output) for calculating DCeP (power efficiency).

In the present embodiment, “task” refers to a series of processing from a certain application's being activated (by receiving information inside a device) and its starting and ending processing for a request to the application, or a series of processing that an application in an activated state receives a request from outside, starts processing, and returns a completion notification to a request source.

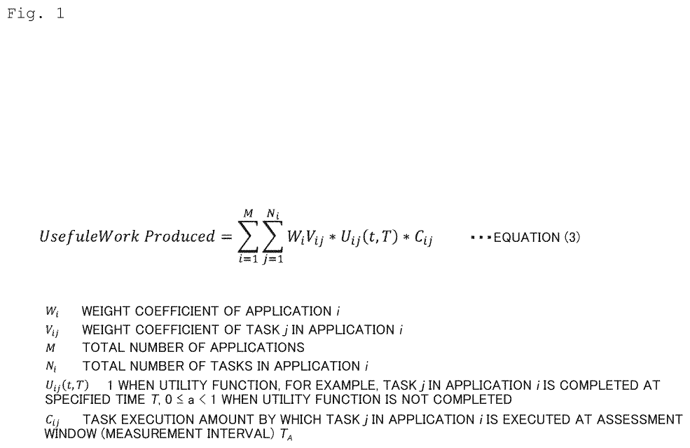

Further, in the present embodiment, the power efficiency calculation device 1 calculates the “useful work produced” (work output) of above Equation (1) as a total value of all task execution amounts of a measurement target executed by a plurality of applications as shown in Equation (3) in FIG. 1. One or more kinds of tasks are executed in one application. In addition, the weight coefficient is defined as “the weight coefficient of the application: W” and “the weight coefficient of the task: V.”

Further, the power efficiency calculation device 1 uses, as a weight determination scheme, two scheme: (1) normalization of task execution amount and (2) group classification by importance.

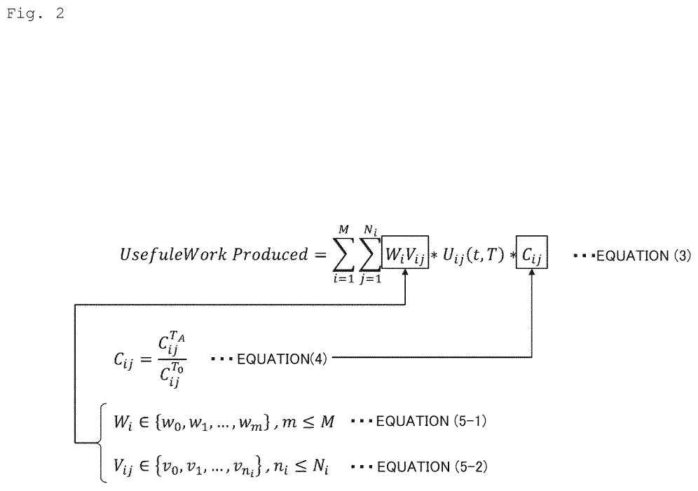

(1) In the “normalization of task execution amount,” a task amount Cᵢⱼ^{TA} executed by an assessment window T_{A} is divided by a task execution amount Cᵢⱼ^{T0} executed in a certain time, and normalized for each of a plurality of tasks including a plurality of applications. This is intended to calculate power efficiency independent of the task execution amount such as the number of task processing times (for example, the number of times a request is processed). The normalized task amount Cᵢⱼ is shown in Equation (4) in FIG. 2.

(2) In the “group classification by importance,” the weight coefficient is set for each importance group for each of the applications and the tasks.

As shown in Equation (5-1) in FIG. 2, the number of importance groups “m” of the application is equal to or smaller than the number of types “M” of the application, and is classified into “m” importance groups. The weight coefficient “W” of the application is defined as weight coefficients {w₀, w₁, . . . , w_{M}} of the respective groups of the applications.

Further, as shown in Equation (5-2) of FIG. 2, the number of task importance groups “nᵢ” is equal to or smaller than the number of task types “Nᵢ,” and is classified into “n-” importance groups. The weight coefficient “Vᵢⱼ” of the task is defined as weight coefficients {v₀, v₁, . . . , vnᵢ} of the respective groups of the tasks.

That is, the number of the importance groups of the applications is set to the number equal to or smaller than the number of types of target applications to be classified, and the weight coefficient is defined for each importance group. Each application is assigned to one of the importance groups in advance according to its importance. Similarly, the number of the tasks is set to the number equal to or smaller than the number of types of target tasks to be classified, and the weight coefficient is defined for each importance group. Each task is assigned to one of the importance groups in advance according to its importance. The weight coefficient of each application and the weight coefficient of each corresponding task are multiplied and used for calculation of a task amount of the application.

Thus, the power efficiency calculation device 1 can calculate DCeP (power efficiency) in a form reflecting the importance of each application and each task without depending on a processing amount for the “useful work produced” (work output) of a plurality of applications or an application having a plurality of tasks.

FIG. 3 is a diagram illustrating an overall configuration of a power efficiency calculation system 1000 including the power efficiency calculation device 1 according to the present embodiment.

The power efficiency calculation system 1000 includes, for example, a physical server group 30 configured of a data center or the like, and the power efficiency calculation device 1 communicatively connected to a physical server group 30.

The physical server group 30 is operated, for example, with a virtualization infrastructure constructed on physical servers, and one or more applications 3 are installed on a virtual machine (VM) or a container on a virtual OS to execute processing. Each application 3 implements a service by executing one or more tasks.

The power efficiency calculation device 1 collects metrics which are assessment indexes required for calculating DCeP (power efficiency) from the physical server group 30, and calculates power efficiency in consideration of importance of applications or tasks.

Hereinafter, a function of the power efficiency calculation device 1 is described in detail.

As illustrated in FIG. 3, the power efficiency calculation device 1 includes a control unit 10, an input and output unit 11, and a storage unit 12.

The input and output unit 11 inputs or outputs information to or from, for example, each server in the physical server group 30. The input and output unit 11 includes a communication interface for performing information transmission or reception via a communication line, and an input and output interface for performing information input or output to and from an input device such as a keyboard and an output device such as a monitor (not illustrated).

The storage unit 12 includes a hard disk, a flash memory, a random access memory (RAM), etc.

The storage unit 12 temporarily stores a program for causing functions of the control unit 10 to be executed or information that is necessary for processing of the control unit 10. Further, a metrics collection database (DB) 100 of the storage unit 12 stores metrics necessary for calculation of DCeP (power efficiency) that are collected from each physical server in the physical server group 30, a virtual OS (OS), a VM, a container, an application, or the like.

The control unit 10 controls the entire processing executed by the power efficiency calculation device 1, and as illustrated in FIG. 3, includes a metrics collection unit 101, a task execution amount normalization unit 102, an importance group setting unit 103, and a power efficiency calculation unit 104.

The metrics collection unit 101 collects metrics (assessment indexes such as performance) necessary for power efficiency calculation from the physical server group 30, and stores the metrics in the metrics collection DB 100.

The metrics collection unit 101 collects metrics from a physical server, an OS (virtual OS), a VM/container, an application, or the like constituting the physical server group 30 by using existing resource monitoring software (for example, Prometheus).

For example, the metrics collection unit 101 collects information on the number of times the request is processed as a task execution amount and power consumption W from the physical server group 30, and stores the information in the metrics collection DB 100.

The metrics collection unit 101 collects the metrics from the physical server group 30 in advance before calculating the DCeP (power efficiency), which is described below as a “preliminary preparation stage”, and also collects metrics when calculating the DCeP (power efficiency), which is described below as an “operation stage”.

The task execution amount normalization unit 102 determines a normalization coefficient by using a task execution amount (for example, the number of times the request is processed) stored as metrics in the metrics collection DB 100.

Specifically, the task execution amount normalization unit 102 acquires information on the task execution amount (number of times the request is processed) executed in each task of each application in a certain period (for example, one day), and extracts a maximum value (maximum number of times the request is processed in the period) of the task execution amount in a predetermined data section (for each predetermined measurement time) for each task of each application. The task execution amount normalization unit 102 determines the normalization coefficient for each task of each application, to be an inverse number of the extracted maximum value of the task execution amount.

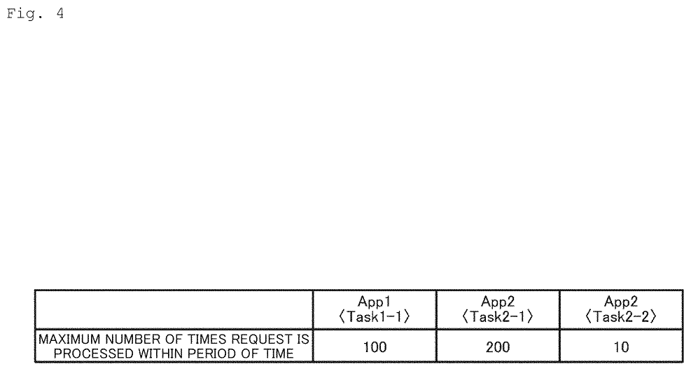

Here, it is assumed that, as illustrated in FIG. 4, for example, the maximum number of times the request is processed in the period is “100” in Task “1-1” of App “1”, “200” in Task “2-1” of App “2”, and “10” in Task “2-2” of App “2”. In this case, the task execution amount normalization unit 102 determines the normalization coefficient for each task to be 1/100, 1/200, and 1/10, respectively.

Note that the task execution amount normalization unit 102 determines a task execution amount CTO executed in a certain time in Equation (4) of FIG. 2 described above as the maximum number of times the request is processed within the period and “1/Cᵢⱼ^{T0}” the normalization coefficient.

Referring back to FIG. 3, the importance group setting unit 103 configures an importance group regarding the application and the task on the basis of a predetermined importance group setting logic.

The importance group setting unit 103 employs, for example, three logics as follows as the predetermined importance group setting logics.

### <<Importance Group Setting Logic “1”>>

The importance group setting logic “1” is a “scheme of using a business-related Key Performance Indicator (KPI)”. KPI is an index for performance management assessment of sales and the like.

The importance group setting unit 103 configures the importance group by using the business-related KPI such as sales and profit of each application and task.

For example, the importance group setting unit 103 sets four kinds of groups of which an order of sales by respective applications to the upper 5%, 5 to 15%, 15 to 50%, 50% or less when viewed from all the applications.

Further, for example, the importance groups are prepared by the number of tasks with a sales ratio of each task as a coefficient.

Thus, the importance group setting logic “1” sets the importance groups of the application and the task by using the business-related KPI.

### <<Importance Group Setting Logic “2”>>

The importance group setting logic “2” is a “scheme of using a function classification of the application”.

The importance group setting unit 103 sets the importance groups for the application and the task by using the importance of each function classification of the application and the task.

The importance group setting unit 103 sets the importance group which has higher importance in an order of Crate→Update→Delete→Read among respective controls of Crate/Read/Update/Delete, for example, in a case of an application regarding resource control.

Further, in the case of an application regarding session control, for example, the importance group setting unit 103 sets the importance group which has a higher importance in an order of session establishment, session update, session disconnection, session maintenance, and retransmission processing.

Thus, the importance group setting logic “2” sets the importance group according to the function classification of the application or task.

### <<Importance Group Setting Logic “3”>>

The importance group setting logic “3” is a “scheme of using task processing metrics of an application”.

The importance group setting unit 103 sets the importance group by using metrics regarding the task processing result of the application.

The importance group setting unit 103 sets four types of groups of upper 5%, 5 to 15%, 15 to 50%, and 50% or less, for example, in each of metrics such as a CPU use rate, a memory use rate, the number of requests, a turn around time (TAT) of task processing, and I/O throughput.

Thus, the importance group setting logic “3” sets the importance group by using the task processing metrics of the application.

When the importance group setting unit 103 performs setting of the importance group regarding the application and the task using the importance group setting logic, the importance group setting unit 103 sets a weight coefficient according to the importance (a weight coefficient which becomes a greater value as the importance group has a higher importance) for each importance group.

The power efficiency calculation unit 104 calculates DCeP (power efficiency) by using metrics (for example, the number of times the request is processed or power consumption) collected by the metrics collection unit 101.

More specifically, the power efficiency calculation unit 104 calculates “Useful Work produced” (work output) by using Equation (3) described above. In this case, the normalized task amount Cᵢⱼ shown in Equation (4) is a value obtained by multiplying the task amount Cᵢⱼ^{TA} executed in an assessment window T_{A} which is a preset measurement period (predetermined assessment period), by the normalization coefficient calculated by the task execution amount normalization unit 102. Further, for the weight coefficient “Wᵢ” of the application and the weight coefficient “Vᵢⱼ” of the task, weight coefficients {w₀, w₁, . . . , wₘ} of the respective importance groups of applications set by the importance group setting unit 103, and weight coefficients {v₀, v₁, . . . , vnᵢ} of the respective groups of tasks are used.

The power efficiency calculation unit 104 calculates DCeP (power efficiency) by using the above-described Equation (1). Here, the value calculated by Equation (3) is used for “Useful Work produced” (work output). Further, for a “total energy consumed to Perform that Work” (power consumption), total power consumption consumed by the physical server group 30 in the assessment window T_{A} which is the preset measurement period (predetermined assessment period) is used. The total power consumption consumed by the physical server group 30 is calculated by, for example, summing the power consumption collected as the metrics in the preset measurement period (predetermined assessment period).

### <Processing of Power Efficiency Calculation Device>

Next, a flow of processing performed by the power efficiency calculation device 1 is described.

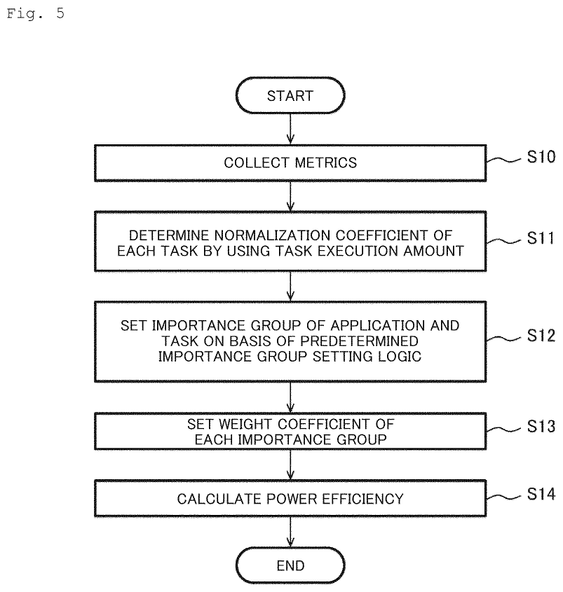

FIG. 5 is a flowchart illustrating an example of a flow of processing executed by the power efficiency calculation device 1 according to the present embodiment.

The processing executed by the power efficiency calculation device 1 is roughly divided into the preliminary preparation stage and the operation stage. In the preliminary preparation stage, the normalization coefficient of the task execution amount is calculated by using the metrics collected from the physical server group 30 in advance, the importance group of the application and the task is set, and a weight coefficient for each importance group is determined. In the operation stage, DCeP (power efficiency) is calculated using the normalization coefficient calculated in the preliminary preparation stage and the weight coefficient for each importance group.

Here is described an example in which, as illustrated in FIG. 3, two applications including App “1” and App “2” are installed on the physical server group 30, one task (task 1-1) is executed in App “1”, and two tasks (task 2-1 and task 2-2) are executed in App “2”.

First, in the preliminary preparation stage, the metrics collection unit 101 of the power efficiency calculation device 1 collects the metrics (assessment indexes such as performance) necessary for power efficiency calculation from the physical server group 30, and stores the metrics in the metrics collection DB 100 (step S10).

The metrics collection unit 101 collects the metrics using, for example, resource monitoring software (Prometheus). The collected metrics are, for example, the number of times the request is processed as a task execution amount and power consumption W.

The collection of the metrics by the metrics collection unit 101 may be performed by, for example, applying a test load to the application 3, or may be performed by collecting metrics obtained by executing actual request processing.

Subsequently, the metrics collection unit 101 outputs information on the task execution amount (the number of times the request is processed) obtained in a certain period (for example, one day) among the collected metrics to the task execution amount normalization unit 102.

The task execution amount normalization unit 102 of the power efficiency calculation device 1 determines the normalization coefficient of each task by using the acquired task execution amount (number of times the request is processed) (step S11).

For example, the task execution amount normalization unit 102 extracts the maximum value of the task execution amount (maximum number of times the request is processed in the period) in a predetermined data section (each predetermined measurement time, for example, 10 minutes) in the acquired task execution amount for one day, for each task of each application (see FIG. 4). The task execution amount normalization unit 102 determines a value obtained by taking an inverse number of the extracted maximum value of the task execution amount as the normalization coefficient for each task of each application. In the example illustrated in FIG. 4, the task execution amount normalization unit 102 determines normalization coefficients of tasks “1-1”, “2-1”, and “2-2” to be 1/100, 1/200, and 1/10.

Next, the importance group setting unit 103 of the power efficiency calculation device 1 sets the importance group of the application and the task on the basis of the predetermined importance group setting logic (step S12).

In the predetermined importance group setting logic, “a scheme of using a business-related KPI”, “a scheme of using function classification of an application”, “a scheme of using task processing metrics of an application”, and the like are preset.

Subsequently, the importance group setting unit 103 sets a weight coefficient according to the importance of the set importance group (step S13). The importance group setting unit 103 sets a weight coefficient which has a greater value as the importance group has a higher importance, as a weight coefficient according to the importance of the importance group of the application and the task.

Here, it is assumed that “a scheme of using business-related KPI” is used as the predetermined importance group setting logic. When a sales amount of each application 3 is App1/App2=90/10, the importance group setting unit sets two importance groups respectively including App1 and App2 and then determines the weight coefficient of each importance group to be {W_{APP1}, W_{APP2}}={0.9, 0.1]

Further, because the task of App 1 is one Task “1-1”, the weight coefficient of Task “1-1” is set to {V_{App1 Task1}}={1}. It is also assumed that “a scheme of using function classification of an application” is used as the predetermined importance group setting logic for a task. Assuming that Task “2-1”/Task “2-2” of App2 are processing corresponding to Create/Delate, the importance group setting unit 103 determines the weight coefficient of the task of App2 to be {V_{Ap2 Task1}, V_{App2 Task2}}={2, 1}, for example.

The processing of steps S10 and S13 is performed in the preliminary preparation stage.

Next, processing in the operation stage is described.

The power efficiency calculation unit 104 of the power efficiency calculation device 1 acquires metrics (task execution amount (the number of times the request is processed) and power consumption) collected by the metrics collection unit 101 from the metrics collection DB 100 in a predetermined assessment period (assessment window TA) that is actual DCeP (power efficiency) calculation target, and calculates DCeP (power efficiency) (step S14). The power efficiency calculation unit 104 repeats processing for calculating the DCeP (power efficiency) for each predetermined assessment period.

Specifically, the power efficiency calculation unit 104 calculates the “Useful Work produced” (work output) through the above-described Equation (3), by using the normalization coefficient calculated by the task execution amount normalization unit 102 and the weight coefficient of the application and the task determined by the importance group setting unit 103. Further, the power efficiency calculation unit 104 obtains the “total energy consumed to Perform that Work” (power consumption) in the above-described Equation (1), by, for example, summing the power consumption collected by the metrics collection unit 101 in the predetermined assessment period (assessment window TA). The power efficiency calculation unit 104 calculates DCeP (power efficiency) through the above-described Equation (1) by using the calculated “Useful Work produced” (work output) and “Total Energy Consumed to Perform Work” (power consumption).

As described above, the power efficiency calculation device 1 can calculate the work output executed by one or more applications and tasks of applications as a quantitative numerical value reflecting the importance of the applications and tasks without depending on a simple processing amount of the applications. The power efficiency calculation device 1 can calculate power efficiency reflecting importance of the application and the task.

### <Hardware Configuration>

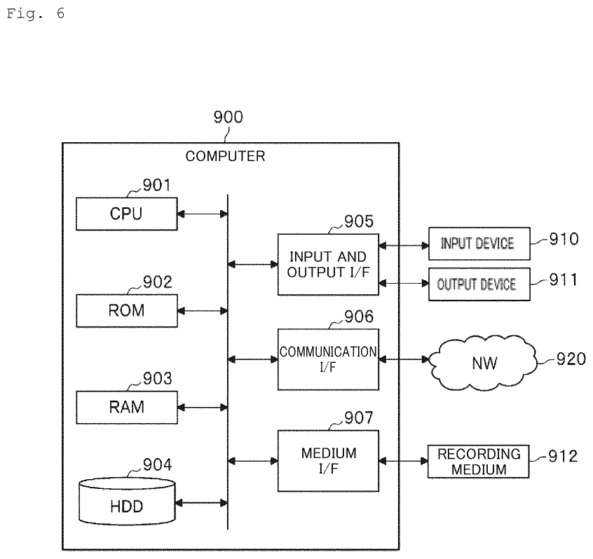

The power efficiency calculation device 1 according to the present embodiment is constructed by, for example, a computer 900 having a configuration as illustrated in FIG. 6.

FIG. 6 is a hardware configuration diagram illustrating an example of the computer 900 that achieves the function of the power efficiency calculation device 1 according to the present embodiment. The computer 900 includes a central processing unit (CPU) 901, a read only memory (ROM) 902, a RAM 903, a hard disk drive (HDD) 904, an input and output interface (I/F) 905, a communication I/F 906, and a medium I/F 907.

The CPU 901 operates on the basis of a program stored in the ROM 902 or the HDD 904 and performs control by the control unit 10 (FIG. 3). The ROM 902 stores a boot program executed by the CPU 901 when the computer 900 is started, a program related to hardware of the computer 900, and the like.

The CPU 901 controls an input device 910 such as a mouse or a keyboard, and an output device 911 such as a display or a printer through the input and output I/F 905. The CPU 901 acquires data from the input device 910 through the input and output I/F 905, and outputs generated data to the output device 911.

The HDD 904 stores a program executed by the CPU 901, data used by the program, and the like. The communication I/F 906 receives data from another device through a communication network (for example, a NW (Network) 920), outputs the data to the CPU 901, and transmits data generated by the CPU 901 to other devices through the communication network.

The medium I/F 907 reads a program or data stored in a recording medium 912 and outputs the program or data to the CPU 901 through the RAM 903. The CPU 901 loads a program related to desired processing from the recording medium 912 onto the RAM 903 through the medium I/F 907, and executes the loaded program. The recording medium 912 is an optical recording medium such as a digital versatile disc (DVD) or a phase change rewritable disk (PD), a magnetooptic recording medium such as a magneto optical disk (MO), a magnetic recording medium, a semiconductor memory, or the like.

For example, when the computer 900 serves as the power efficiency calculation device 1 according to the present embodiment, the CPU 901 of the computer 900 implements the function of the power efficiency calculation device 1 by executing a program loaded onto the RAM 903. Further, data in the RAM 903 is stored in the HDD 904. The CPU 901 reads the program related to the desired processing from the recording medium 912 and executes the program. In addition, the CPU 901 may read the program related to the desired processing from another device through a communication network (NW 920).

### <Effects>

Hereinafter, effects of the power efficiency calculation device 1 and the like according to the present invention is described.

A power efficiency calculation device 1 according to the present invention is a power efficiency calculation device for calculating power efficiency by executing an application 3 installed on a physical server group 30, in which one or more applications 3 for executing one or more tasks are installed in the physical server group 30, and the power efficiency calculation device 1 includes a metrics collection unit 101 configured to collect metrics from the physical server group 30, the metrics being an assessment index necessary for power efficiency calculation and including a task execution amount and power consumption of the physical server group 30, and to store the metrics in a metrics collection DB 100 in a storage unit 12; a task execution amount normalization unit 102 configured to acquire the task execution amount stored in the metrics collection DB 100 and determine a normalization coefficient for each task of each application 3 by using the task execution amount measured for each predetermined measurement time; an importance group setting unit 103 configured to perform setting of an importance group regarding each of the applications 3 and each task on the basis of a predetermined importance group setting logic, and to set a weight according to importance of each of an importance group of each application 3 and an importance group of each task; and a power efficiency calculation unit 104 configured to acquire metrics of a predetermined assessment period collected by the metrics collection unit 101, normalize the task execution amount by using the normalization coefficient for each task of each application 3 for the task execution amount included in the metrics, calculate a total work output using the normalized task execution amount and a weight of each importance group of each application 3 and each task, and calculate power efficiency from the power consumption included in the metrics and the total work output.

Thus, the power efficiency calculation device 1 can calculate the work output of a work executed by one or more applications and tasks of the applications as a quantitative numerical value reflecting the importance of the applications and tasks without depending on a simple processing amount of the applications. Thus, the power efficiency calculation device 1 can calculate power efficiency reflecting importance of the application and the task.

Further, in the power efficiency calculation device 1, the task execution amount normalization unit 102 extracts a maximum value among task execution amounts measured during predetermined measurement time, for each task of each application 3, and determines a value obtained by taking an inverse number of the extracted maximum value of task execution amount as the normalization coefficient for each task of each application 3.

Thus, the power efficiency calculation device 1 can determine the normalization coefficient so that it does not depend on a degree of the task execution amount (processing amount) for each task of each application, and normalize the task execution amount.

In the power efficiency calculation device 1, the predetermined importance group setting logic is a logic configured to set an importance group using a Key Performance Indicator (KPI) including sales of each of the application 3 and the task.

Thus, the power efficiency calculation device 1 can set the importance groups of the application and the task by using the KPI and set the weight coefficient of each importance group.

Further, in the power efficiency calculation device 1, the predetermined importance group setting logic is a logic configured to set the importance group by using a function classification of the application 3 and the task.

Thus, the power efficiency calculation device 1 can set the importance groups of the application 3 and the task by using the function classification of the application 3 and the task, and set the weight coefficient of each importance group.

Further, in the power efficiency calculation device 1, the predetermined importance group setting logic is a logic configured to set the importance group by using metrics obtained by collecting task processing results of each application 3.

Thus, the power efficiency calculation device 1 can set the importance groups of the applications 3 and tasks by using the task processing results of the respective applications 3, and set the weight coefficients of the respective importance groups.

The present invention is not limited to the embodiment described above, and various modifications can be made by a person of ordinary skill in the art within the technical idea of the present invention.

### REFERENCE SIGNS LIST

1 Power efficiency calculation device
3 Application (App)
10 Control unit
11 Input and output unit
12 Storage unit
30 Physical server group
100 Metrics collection DB
101 Metrics collection unit
102 Task execution amount normalization unit
103 Importance group setting unit
104 Power efficiency calculation unit
1000 Power efficiency calculation system

1. A power efficiency calculation device for calculating power efficiency by executing an application installed on a physical server group,
wherein one or more applications for executing one or more tasks are installed in the physical server group, and
the power efficiency calculation device comprises:
a metrics collection unit configured to collect metrics from the physical server group, the metrics being an assessment index necessary for power efficiency calculation and including a task execution amount and power consumption of the physical server group, and to store the metrics in a metrics collection DB in a storage unit;
a task execution amount normalization unit configured to acquire the task execution amount stored in the metrics collection DB and to determine a normalization coefficient for each task of each application by using the task execution amount measured for each predetermined measurement time;
an importance group setting unit configured to perform setting of an importance group regarding each application and each task on a basis of a predetermined importance group setting logic, and to set a weight according to importance of each of an importance group of each application and an importance group of each task; and
a power efficiency calculation unit configured to acquire metrics of a predetermined assessment period collected by the metrics collection unit, to normalize the task execution amount by using the normalization coefficient for each task of each application for the task execution amount included in the metrics, to calculate a total work output using the normalized task execution amount and a weight of each importance group of each application and each task, and to calculate power efficiency from the power consumption included in the metrics and the total work output.

2. The power efficiency calculation device according to claim 1, wherein the task execution amount normalization unit is configured to extract a maximum value among task execution amounts measured for a predetermined measurement time for each task of each application, and configured to determine a value obtained as an inverse number of the extracted maximum value of the task execution amount as the normalization coefficient for each task of each application.

3. The power efficiency calculation device according to claim 1,
wherein the predetermined importance group setting logic is a logic configured to set an importance group using a key performance indicator (KPI) including sales of each application and task.

4. The power efficiency calculation device according to claim 1,
wherein the predetermined importance group setting logic is a logic configured to set the importance group using a function classification of the application and the task.

5. The power efficiency calculation device according to claim 1,
wherein the predetermined importance group setting logic is a logic configured to set the importance group using metrics obtained by collecting a task processing result of each application.

6. A power efficiency calculation method for a power efficiency calculation device for calculating power efficiency by executing an application installed on a physical server group,
wherein one or more applications for executing one or more tasks are installed in the physical server group, and
the power efficiency calculation device executes:
collecting metrics from the physical server group, the metrics being an assessment index necessary for power efficiency calculation and including a task execution amount and power consumption of the physical server group, and storing the metrics in a metrics collection DB in a storage unit;
acquiring the task execution amount stored in the metrics collection DB and determining a normalization coefficient for each task of each application by using the task execution amount measured for each predetermined measurement time;
performing setting of an importance group regarding each application and each task on a basis of a predetermined importance group setting logic, and setting a weight according to importance of each of an importance group of each application and an importance group of each task; and
acquiring metrics collected in a predetermined assessment period, normalizing the task execution amount by using the normalization coefficient for each task of each application for the task execution amount included in the metrics, calculating a total work output using the normalized task execution amount and a weight of each importance group of each application and each task, and calculating power efficiency from the power consumption included in the metrics and the total work output.

7. A power efficiency calculation system comprising: a physical server group on which one or more applications for executing one or more tasks are installed, and a power efficiency calculation device for calculating power efficiency by executing an application installed on the physical server group,
wherein the power efficiency calculation device includes:
a metrics collection unit configured to collect metrics from the physical server group, the metrics being an assessment index necessary for power efficiency calculation and including a task execution amount and power consumption of the physical server group, and store the metrics in a metrics collection DB in a storage unit;
a task execution amount normalization unit configured to acquire the task execution amount stored in the metrics collection DB and determine a normalization coefficient for each task of each application by using the task execution amount measured for each predetermined measurement time;
an importance group setting unit configured to perform setting of an importance group regarding each application and each task on a basis of a predetermined importance group setting logic, and to set a weight according to importance of each of an importance group of each application and an importance group of each task; and
a power efficiency calculation unit configured to acquire metrics of a predetermined assessment period collected by the metrics collection unit, to normalize the task execution amount by using the normalization coefficient for each task of each application for the task execution amount included in the metrics, to calculate a total work output using the normalized task execution amount and a weight of each importance group of each application and each task, and calculate power efficiency from the power consumption included in the metrics and the total work output.

8. A non-transitory computer-readable storage medium storing a program for causing a computer to function as the power efficiency calculation device according to claim 1.
